(19) United States
(12) Patent Application Publication
(10) Pub. No.: US 2026/0164676 A1
(43) Pub. Date: Jun. 11, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Nam Kyun PARK, Icheon-si (KR)

(21) Appl. No.: 19/195,122

(22) Filed: Apr. 30, 2025

(30) Foreign Application Priority Data
Dec. 11, 2024 (KR) 10-2024-0183752

(51) Int. Cl. H10B 63/00

(52) U.S. Cl. CPC H10B 63/80

(57) ABSTRACT

A semiconductor device includes: row lines extending in a first direction; column lines extending in a second direction that intersects the first direction; memory cells located at intersection regions between the row lines and the column lines; first liner layers formed on sidewalls of the row lines and sidewalls of the memory cells; first gap-fill insulating layers located between the memory cells adjacent to each other in the second direction; and first oxygen adsorption layers located between the first liner layers and the first gap-fill insulating layers and spaced apart from the column lines.

### CROSS-REFERENCE TO RELATED APPLICATION

This application claims priority under 35 U.S.C. § 119 to Korean Patent Application No. 10-2024-0183752 filed on Dec. 11, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like, of electronic devices, semiconductor devices capable of storing information have been desirable in various electronic devices such as computers and portable communication devices. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), and the like.

### SUMMARY

In an embodiment, a semiconductor device may include: row lines extending in a first direction; column lines extending in a second direction that intersects the first direction; memory cells located at intersection regions between the row lines and the column lines; first liner layers formed on sidewalls of the row lines and sidewalls of the memory cells; first gap-fill insulating layers located between the memory cells adjacent to each other in the second direction; and first oxygen adsorption layers located between the first liner layers and the first gap-fill insulating layers and spaced apart from the column lines.

In an embodiment, a semiconductor device may include: first row lines extending in a first direction; first column lines extending in a second direction that intersects the first direction; first memory cells located between the first row lines and the first column lines; first liner layers formed on sidewalls of the first memory cells and sidewalls of the first column lines; first gap-fill insulating layers located between the first memory cells adjacent to each other in the first direction; and first oxygen adsorption layers located between the first liner layers and the first gap-fill insulating layers.

In an embodiment, a method of manufacturing a semiconductor device may include: forming row lines that extend in a first direction; forming cell lines that extend in the first direction; forming a first liner layer on the cell lines; forming a first oxygen adsorption layer on the first liner layer; etching the first oxygen adsorption layer to form a plurality of etched first oxygen adsorption layers so that an upper surface of each of the etched first oxygen adsorption layers is located lower than upper surfaces of the cell lines; and forming a first gap-fill insulating layer between a pair of the cell lines adjacent to each other.

In an embodiment, a method of manufacturing a semiconductor device may include: forming row lines that extend in a first direction; forming column lines that extend in a second direction intersecting the first direction; forming first memory cells arranged in the first direction and the second direction between the row lines and the column lines; forming liner layers on sidewalls of the column lines and sidewalls of the first memory cells; forming an oxygen adsorption layer on the liner layers; and forming a first gap-fill insulating layer between a pair of the first memory cells adjacent to each other in the first direction.

### BRIEF DESCRIPTION OF THE DRAWINGS

FIGS. 1A, 1B, and 1C are diagrams illustrating the structure of a semiconductor device in accordance with an embodiment.

FIGS. 2A and 2B are diagrams illustrating the structure of a semiconductor device in accordance with an embodiment.

FIGS. 3A and 3B are diagrams illustrating the structure of a semiconductor device in accordance with an embodiment.

FIGS. 4A and 4B are diagrams illustrating the structure of a semiconductor device in accordance with an embodiment.

FIGS. 5A and 5B are diagrams illustrating the structure of a semiconductor device in accordance with an embodiment.

FIGS. 6A, 7A, and 8A, FIGS. 6B, 7B, and 8B, and FIGS. 6C, 7C, and 8C are diagrams for describing a manufacturing method of a semiconductor device in accordance with an embodiment.

FIGS. 9A, 10A, and 11A, FIGS. 9B, 10B, and 11B, and FIGS. 9C, 10C, and 11C are diagrams for describing a manufacturing method of a semiconductor device in accordance with an embodiment.

FIGS. 12A, 13A, and 14A, FIGS. 12B, 13B, and 14B, and FIGS. 12C, 13C, and 14C are diagrams for describing a manufacturing method of a semiconductor device in accordance with an embodiment.

FIGS. 15A, 16A, and 17A, FIGS. 15B, 16B, and 17B, and FIGS. 15C, 16C, and 17C are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By forming memory cells in the form of a cross point array, it is possible to improve the degree of integration of a semiconductor device. It is also possible to provide a semiconductor device having a stable structure and improved reliability.

Hereafter, some embodiments of the present disclosure will be described with reference to the accompanying drawings. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B). Moreover, a first element “on” a second element indicates that the first element can be “directly on” the second element, or that at least one intervening element can be interposed between the first and second elements.

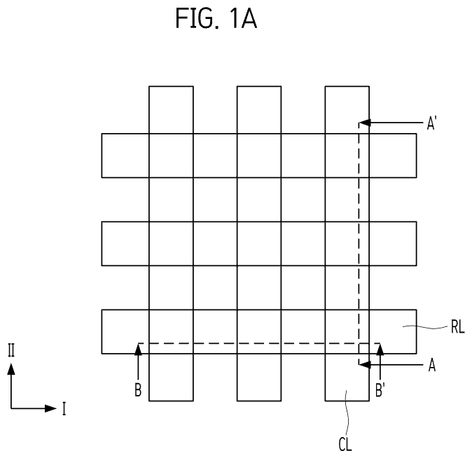

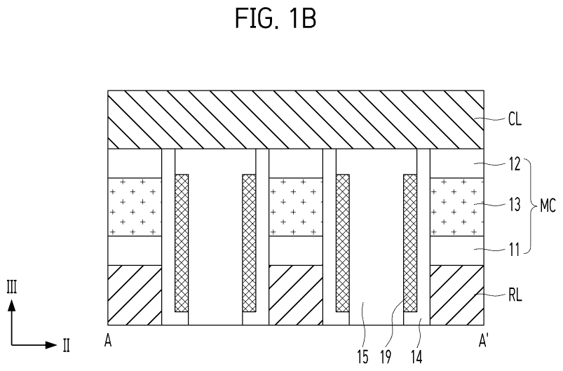

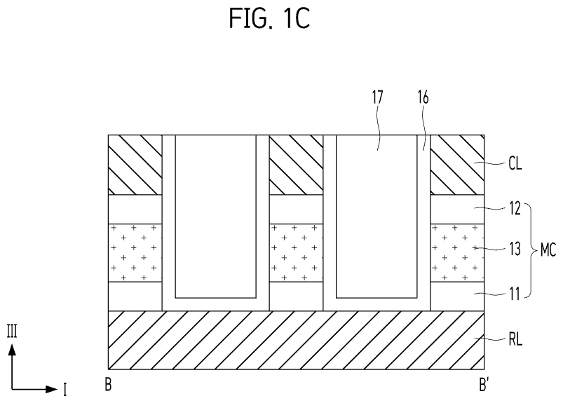

FIGS. 1A to 1C are diagrams illustrating the structure of a semiconductor device in accordance with an embodiment. FIG. 1A is a layout diagram, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device includes row lines RL, column lines CL, memory cells MC, first liner layers 14, oxygen adsorption layers 19, and first gap-fill insulating layers 15. The semiconductor device may further include second liner layers 16 and second gap-fill insulating layers 17.

The row lines RL may extend in a first direction I, and the column lines CL may extend in a second direction II intersecting the first direction I. The row lines RL and the column lines CL may be stacked in a third direction III. The third direction III may be a direction perpendicular to a plane defined by the first direction I and the second direction II. The row lines RL may be word lines, and the column lines CL may be bit lines. Alternatively, the row lines RL may be bit lines, and the column lines CL may be word lines.

The memory cells MC may be located at intersection regions between the row lines RL and the column lines CL. The memory cells MC may be arranged in the first direction I and the second direction II. Each memory cell MC may include a first electrode 11, a second electrode 12, and a variable resistance layer 13. The variable resistance layer 13 may be located between the first electrode 11 and the second electrode 12.

The variable resistance layer 13 may have characteristics that it reversibly transitions between different resistance states depending on a voltage or a current applied to the memory cell MC. As an example, when the variable resistance layer 13 has a low resistance state, data ‘1’ may be stored, and when the variable resistance layer 13 has a high resistance state, data ‘0’ may be stored.

As an example, the variable resistance layer 13 may include a resistive material. An electrical path is generated or disappears in the variable resistance layer 13, such that data may be stored. As an example, the variable resistance layer 13 may include transition metal oxide or include metal oxide such as a perovskite-based material.

As an example, the variable resistance layer 13 may have a magnetic tunnel junction (MTJ) structure including a magnetization pinned layer, a tunnel barrier layer, and a magnetization free layer. The data may be stored according to a change in magnetization direction of the magnetization free layer with respect to a magnetization direction of the magnetization pinned layer. As an example, the magnetization pinned layer and the magnetization free layer may each include a magnetic material, and the tunnel barrier layer may include metal oxide.

As an example, the variable resistance layer 13 may include a phase change material or include a chalcogenide-based material. The variable resistance layer 13 may change its phase according to a program operation. As an example, the variable resistance layer 13 may have a low resistance crystalline state through a set operation. As an example, the variable resistance layer 13 may have a high resistance amorphous state through a reset operation. Accordingly, the data may be stored in the memory cell MC using a difference in resistance according to the phase of the variable resistance layer 13.

As an example, the variable resistance layer 13 may include a variable resistance material whose resistance changes without a phase change or include a chalcogenide-based material. The variable resistance layer 13 may maintain its phase after the program operation. As an example, the variable resistance layer 13 may have an amorphous state, and may maintain the amorphous state without changing to a crystalline state after the program operation. A threshold voltage of the memory cell MC may be changed depending on a program voltage applied to the memory cell MC, and the memory cell MC may be programmed to at least two states. As an example, the memory cell MC may be programmed to a set state or a reset state using program voltages having different polarities. Accordingly, the data may be stored in the memory cell MC using a difference in the threshold voltage of the memory cell MC.

The first electrode 11 may be electrically connected to the row line RL, and the second electrode 12 may be electrically connected to the column line CL. The first electrode 11 and the second electrode 12 may each include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), aluminum (Al), copper (Cu), zinc (Zn), nickel (Ni), cobalt (Co), lead (Pb), platinum (Pt), molybdenum (Mo), ruthenium (Ru), or the like, or include any combination thereof.

The first liner layers 14 may be formed on sidewalls of the row lines RL and sidewalls of the memory cells MC. In some embodiments, each of the first liner layers 14 may be formed on a sidewall of a corresponding (e.g., abutting) one of the row lines RL and a sidewall of a corresponding (e.g., abutting) one of the memory cell MC. The first liner layers 14 may protect the variable resistance layers 13 in a manufacturing process. The first liner layers 14 may each include nitride, silicon nitride, or the like. The first gap-fill insulating layers 15 may be located between the memory cells MC adjacent to each other in the second direction II. For example, each of the first gap-fill insulating layers 15 is located between a pair of the memory cells MC adjacent to each other in the second direction II. The first gap-fill insulating layers 15 may each include oxide, silicon oxide, or the like.

The oxygen adsorption layers 19 may be located between the first liner layers 14 and the first gap-fill insulating layers 15. In some embodiments, each of the oxygen adsorption layers 19 is located between a corresponding (e.g., abutting) one of the first liner layers 14 and a corresponding (e.g., abutting) one of the first gap-fill insulating layers 15 and is spaced apart from a corresponding (e.g., adjacent to) one of the column lines CL. The oxygen adsorption layers 19 are used to adsorb oxygen in the first gap-fill insulating layers 15. The oxygen adsorption layers 19 may each include a material having a higher reactivity with oxygen than the first liner layers 14. The oxygen adsorption layers 19 may each include metal, metal oxide, or metal and metal oxide. As an example, the oxygen adsorption layers 19 may each include at least one of zirconium (Zr), titanium (Ti), hafnium (Hf), tantalum (Ta), tungsten (W), cobalt (Co), nickel (Ni), silicon (Si), germanium (Ge), lanthanum (La), or aluminum (Al).

When the first liner layers 14 and the first gap-fill insulating layers 15 are in contact with each other, oxygen in the first gap-fill insulating layers 15 may come into contact with the first liner layers 14. For example, the oxygen may be an oxygen gas, an oxygen source gas, or the like, remaining in a gap-fill insulating layer when a gap-fill insulating material is deposited. Physical properties of the first liner layers 14 may be changed due to the remaining oxygen. As an example, the first liner layers 14 may be deteriorated by an oxidation reaction. Accordingly, the oxygen adsorption layers 19 are located between the first liner layers 14 and the first gap-fill insulating layers 15. The metal in the oxygen adsorption layers 19 and the oxygen remaining in the first gap-fill insulating layers 15 may react with each other, and at least a portion of the oxygen adsorption layers 19 may include metal oxide. As a result, the oxygen adsorption layers 19 may effectively block movement of the oxygen from the first gap-fill insulating layers 15 to the first liner layers 14 to substantially prevent deterioration of the first liner layers 14.

The oxygen adsorption layers 19 may be located lower than the memory cells MC. As an example, upper surfaces of the oxygen adsorption layers 19 may be located lower than upper surfaces of the memory cells MC. The oxygen adsorption layers 19 may be spaced apart from the column lines CL. Accordingly, even though the oxygen adsorption layers 19 each include the metal, it is possible to substantially prevent a bridge from occurring between the column lines CL due to the oxygen adsorption layers 19. In other words, the oxygen absorption layer 19 may be sufficiently spaced apart from a lower surface of a corresponding (e.g., adjacent to) column line CL to substantially prevent an occurrence of a bridge between the column lines CL. In some embodiments, the oxygen absorption layer 19 may extend in the third direction III to sufficiently cover a corresponding (e.g., abutting) first liner layer 14 to substantially prevent deterioration of the first liner layer 14. For example, an upper surface of the oxygen absorption layer 19 may be not lower than an upper surface of the variable resistance layer 13 of the memory cell MC.

The second liner layers 16 may be formed on sidewalls of the column lines CL and sidewalls of the memory cells MC. The second liner layers 16 may each include nitride, silicon nitride, or the like. The second gap-fill insulating layers 17 may be located between the memory cells MC adjacent to each other in the first direction I. The second gap-fill insulating layers 17 may each include oxide, silicon oxide, or the like. The second liner layers 16 may surround lower surfaces of the second gap-fill insulating layers 17.

According to the structure described above, by locating the oxygen adsorption layers 19 between the first liner layers 14 and the first gap-fill insulating layers 15, it is possible to protect the first liner layers 14. By locating the oxygen adsorption layers 19 to be lower than the column lines CL, it is possible to substantially prevent the bridge from occurring between the column lines CL. Accordingly, the reliability of the semiconductor device may be improved.

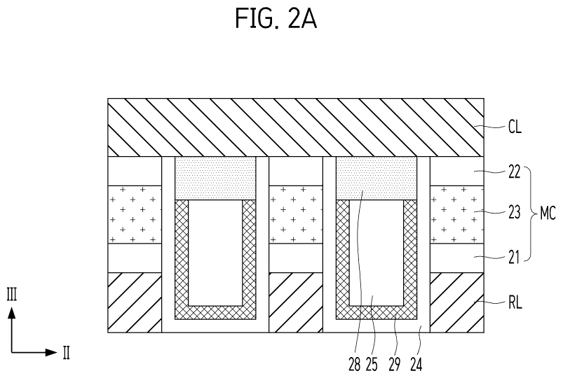

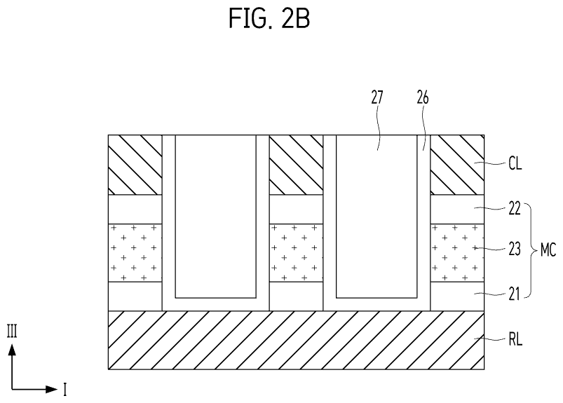

FIGS. 2A and 2B are diagrams illustrating the structure of a semiconductor device in accordance with an embodiment. FIG. 2A is a cross-sectional view in the second direction II, and FIG. 2B is a cross-sectional view in the first direction I. Hereinafter, the content overlapping with the previously described content may be omitted for the interest of brevity.

Referring to FIGS. 2A and 2B, the semiconductor device includes row lines RL, column lines CL, memory cells MC, first liner layers 24, oxygen adsorption layers 29, first gap-fill insulating layers 25, and second gap-fill insulating layers 28. The semiconductor device may further include second liner layers 26 and third gap-fill insulating layers 27.

The row lines RL may extend in the first direction I, and the column lines CL may extend in the second direction II intersecting the first direction I. The memory cells MC may be located at intersection regions between the row lines RL and the column lines CL. Each memory cell MC may include a first electrode 21, a second electrode 22, and a variable resistance layer 23.

The first liner layers 24 may be formed on sidewalls of the row lines RL and sidewalls of the memory cells MC. The first gap-fill insulating layers 25 may be located between the memory cells MC adjacent to each other in the second direction II. The first gap-fill insulating layers 25 may be located lower than the memory cells MC. Upper surfaces of the first gap-fill insulating layers 25 may be located lower than upper surfaces of the memory cells MC.

The oxygen adsorption layers 29 may be located between the first liner layers 24 and the first gap-fill insulating layers 25. The upper surfaces of the first gap-fill insulating layers 25 and upper surfaces of the oxygen adsorption layers 29 may be located on substantially the same plane. In other words, the upper surfaces of the first gap-fill insulating layers 25 may be substantially coplanar with the upper surfaces of the oxygen adsorption layers 29. The oxygen adsorption layers 29 may surround lower surfaces of the first gap-fill insulating layers 25. The first liner layers 24 may surround the lower surfaces of the first gap-fill insulating layers 25. In the cross-sectional view of FIG. 2A, the first liner layers 24 and the oxygen adsorption layers 29 may each have a U shape.

The second gap-fill insulating layers 28 may be located on (e.g., above) the first gap-fill insulating layers 25 and the oxygen adsorption layers 29. The second gap-fill insulating layers 28 may be located between the memory cells MC adjacent to each other in the second direction II. The second gap-fill insulating layers 28 may be located between the oxygen adsorption layers 29 and the column lines CL. Accordingly, the oxygen adsorption layers 29 and the column lines CL may be separated from each other, and the occurrence of a bridge may be reduced (e.g., substantially prevented).

The second gap-fill insulating layers 28 may each include a different material from the first gap-fill insulating layers 25. As an example, the first gap-fill insulating layers 25 may each include oxide, and the second gap-fill insulating layers 28 may each include nitride. By forming the second gap-fill insulating layers 28 using the nitride, it is possible to reduce the oxidation of the first liner layers 24. In some embodiments, the second gap-fill insulating layers 28 may each include substantially the same material as the first liner layers 24. As an example, the second gap-fill insulating layers 28 and the first liner layers 24 may each include nitride. In these embodiments, when the second gap-fill insulating layers 28 are formed using the same material as the first liner layers 24, even though the first liner layers 24 are damaged in a manufacturing process, the first liner layers 24 may be reinforced by the second gap-fill insulating layers 28. As a result, the variable resistance layers 23 may be protected by the first liner layers 24 and the second gap-fill insulating layers 28.

The second liner layers 26 may be formed on sidewalls of the column lines CL and sidewalls of the memory cells MC. The third gap-fill insulating layers 27 may be located between the memory cells MC adjacent to each other in the first direction I. The second liner layers 26 may surround lower surfaces of the third gap-fill insulating layers 27.

According to the structure described above, the second gap-fill insulating layers 28 may be formed on the oxygen adsorption layers 29 and the first gap-fill insulating layers 25. Through this, it is possible to protect the first liner layers 24 and the variable resistance layers 23, while substantially preventing the bridge from occurring between the column lines CL. Accordingly, the reliability of the semiconductor device may be improved.

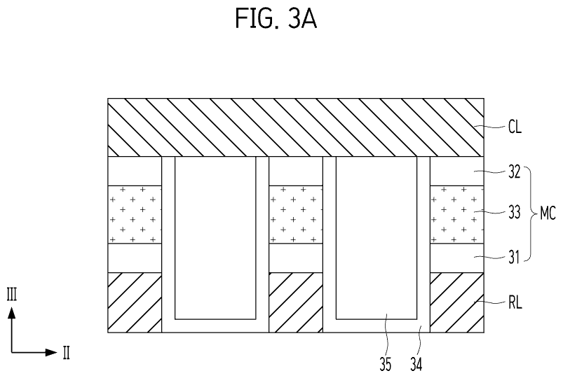

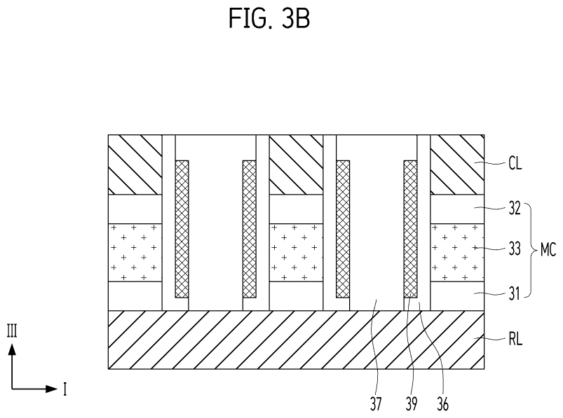

FIGS. 3A and 3B are diagrams illustrating the structure of a semiconductor device in accordance with an embodiment. FIG. 3A is a cross-sectional view in the second direction II, and FIG. 3B is a cross-sectional view in the first direction I. Hereinafter, the content overlapping with the previously described content may be omitted for the interest of brevity.

Referring to FIGS. 3A and 3B, the semiconductor device may include row lines RL, column lines CL, memory cells MC, first liner layers 34, first gap-fill insulating layers 35, second liner layers 36, second gap-fill insulating layers 37, and oxygen adsorption layers 39.

The row lines RL may extend in the first direction I, and the column lines CL may extend in the second direction II. The memory cells MC may be located at intersection regions between the row lines RL and the column lines CL. Each memory cell MC may include a first electrode 31, a second electrode 32, and a variable resistance layer 33.

The first liner layers 34 may be formed on sidewalls of the row lines RL and sidewalls of the memory cells MC. The first gap-fill insulating layers 35 may be located between the memory cells MC adjacent to each other in the second direction II. The first liner layers 34 may surround lower surfaces of the first gap-fill insulating layers 35.

The second liner layers 36 may be formed on sidewalls of the column lines CL and sidewalls of the memory cells MC. The second gap-fill insulating layers 37 may be located between the memory cells MC adjacent to each other in the first direction I.

The oxygen adsorption layers 39 may be located between the second liner layers 36 and the second gap-fill insulating layers 37. In some embodiments, each of the oxygen adsorption layers 39 may be located between a corresponding (e.g., abutting) one of the second liner layers 36 and a corresponding (e.g., abutting) one of the second gap-fill insulating layers 37. The oxygen adsorption layers 39 may be located lower than the column lines CL. As an example, upper surfaces of the oxygen adsorption layers 39 may be located lower than upper surfaces of the column lines CL. In the cross-sectional view of FIG. 3B, the oxygen adsorption layers 39 may each have a spacer shape, and the second gap-fill insulating layers 37 may each have a T shape. The oxygen adsorption layers 39 may each include metal and/or metal oxide.

According to the structure described above, by locating the oxygen adsorption layers 39 between the second liner layers 36 and the second gap-fill insulating layers 37, it is possible to protect the second liner layers 36. Accordingly, damage to the variable resistance layers 33 may substantially be prevented, and the reliability of the semiconductor device may be improved.

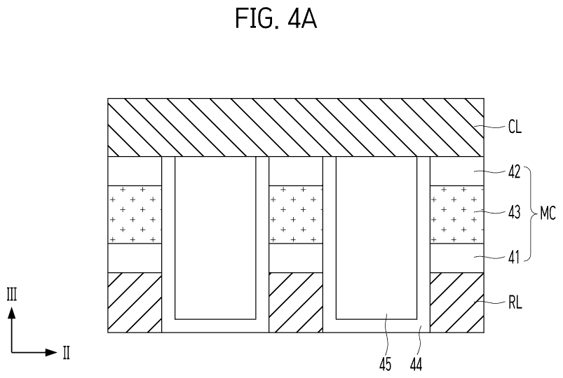

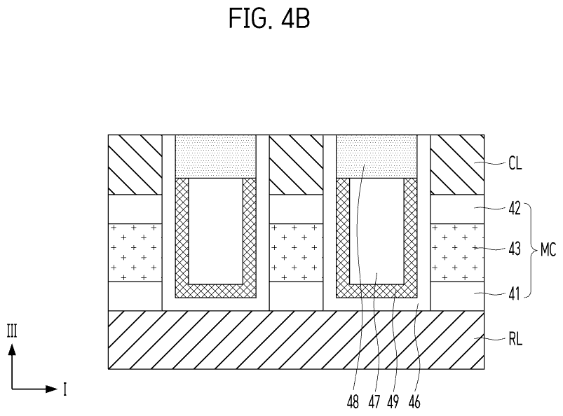

FIGS. 4A and 4B are diagrams illustrating the structure of a semiconductor device in accordance with an embodiment. FIG. 4A is a cross-sectional view in the second direction II, and FIG. 4B is a cross-sectional view in the first direction I. Hereinafter, the content overlapping with the previously described content may be omitted for the interest of brevity.

Referring to FIGS. 4A and 4B, the semiconductor device may include row lines RL, column lines CL, memory cells MC, first liner layers 44, first gap-fill insulating layers 45, second liner layers 46, second gap-fill insulating layers 47, third gap-fill insulating layers 48, and oxygen adsorption layers 49.

The row lines RL may extend in the first direction I, and the column lines CL may extend in the second direction II intersecting the first direction I. The memory cells MC may be located at intersection regions between the row lines RL and the column lines CL. Each memory cell MC may include a first electrode 41, a second electrode 42, and a variable resistance layer 43.

The first liner layers 44 may be formed on sidewalls of the row lines RL and sidewalls of the memory cells MC. The first gap-fill insulating layers 45 may be located between the memory cells MC adjacent to each other in the second direction II.

The second liner layers 46 may be formed on sidewalls of the column lines CL and sidewalls of the memory cells MC. The second gap-fill insulating layers 47 may be located between the memory cells MC adjacent to each other in the first direction I. The second liner layers 46 may surround lower surfaces of the second gap-fill insulating layers 47.

The oxygen adsorption layers 49 may be located between the second liner layers 46 and the second gap-fill insulating layers 47. Upper surfaces of the second gap-fill insulating layers 47 and upper surfaces of the oxygen adsorption layers 49 may be located on substantially the same plane. The oxygen adsorption layers 49 may surround the lower surfaces of the second gap-fill insulating layers 47. Between the memory cells MC adjacent to each other in the first direction I, the oxygen adsorption layers 49 may extend along surfaces of the row lines RL. The second liner layers 46 may surround the oxygen adsorption layers 49. In the cross-sectional view of FIG. 4B, the second liner layers 46 and the oxygen adsorption layers 49 may each have a U shape.

The third gap-fill insulating layers 48 may be located on the second gap-fill insulating layers 47 and the oxygen adsorption layers 49. The third gap-fill insulating layers 48 may be located between the column lines CL adjacent to each other in the first direction I. The third gap-fill insulating layers 48 may each include a different material from the second gap-fill insulating layers 47. As an example, the second gap-fill insulating layers 47 may each include oxide, and the third gap-fill insulating layers 48 may each include nitride. By forming the third gap-fill insulating layers 48 using the nitride, it is possible to reduce the oxidation of the second liner layers 46.

According to the structure described above, the third gap-fill insulating layers 48 may be formed on the oxygen adsorption layers 49 and the second gap-fill insulating layers 47. Through this, the second liner layers 46 and the variable resistance layers 43 may be protected, and the reliability of the semiconductor device may be improved.

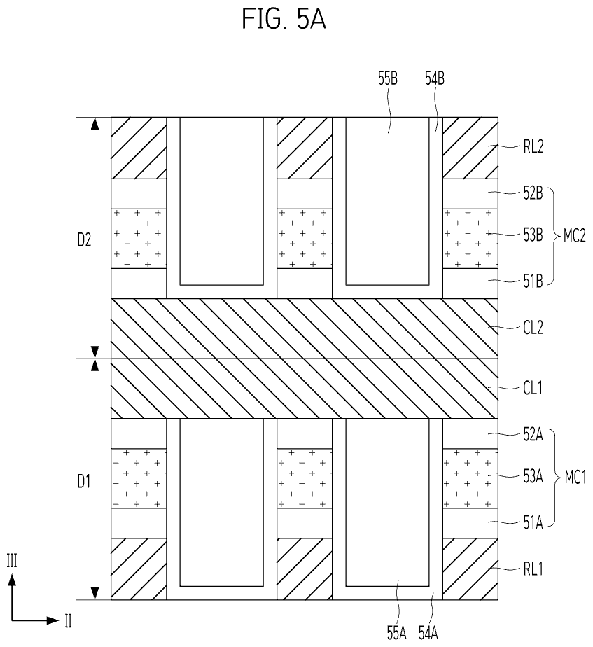

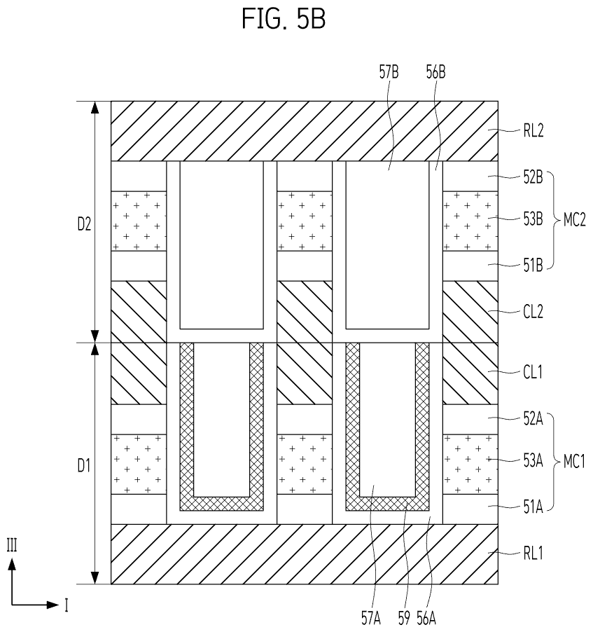

FIGS. 5A and 5B are diagrams illustrating the structure of a semiconductor device in accordance with an embodiment. FIG. 5A is a cross-sectional view in the second direction II, and FIG. 5B is a cross-sectional view in the first direction I. Hereinafter, the content overlapping with the previously described content may be omitted for the interest of brevity.

Referring to FIGS. 5A and 5B, the semiconductor device may include a first deck D1 and a second deck D2. The first deck D1 and the second deck D2 may be stacked in the third direction III. The first deck D1 and/or the second deck D2 may include an oxygen adsorption layer 59.

The first deck D1 may include first row lines RL1, first column lines CL1, first memory cells MC1, first liner layers 54A, first gap-fill insulating layers 55A, second liner layers 56A, and second gap-fill insulating layers 57A.

The first row lines RL1 may extend in the first direction I, and the first column lines CL1 may extend in the second direction II. The first memory cells MC1 may be located at intersection regions between the first row lines RL1 and the first column lines CL1. Each first memory cell MC1 may include a first electrode 51A, a second electrode 52A, and a variable resistance layer 53A.

The first liner layers 54A may be formed on sidewalls of the first row lines RL1 and sidewalls of the first memory cells MC1. The first gap-fill insulating layers 55A may be located between the first memory cells MC1 adjacent to each other in the second direction II.

The second liner layers 56A may be formed on sidewalls of the first column lines CL1 and sidewalls of the first memory cells MC1. For example, each of the second liner layers 56A is formed on the sidewalls of a pair of the first memory cells MC1 adjacent to each other in the first direction I and the sidewalls of a pair of the first column lines CL1 adjacent to each other in the first direction I. The second gap-fill insulating layers 57A may be located between the first memory cells MC1 adjacent to each other in the first direction I. For example, each of the second gap-fill insulating layers 57A is located between a pair of the first memory cells MC1 adjacent to each other in the first direction I.

The oxygen adsorption layers 59 may be located between the second liner layers 56A and the second gap-fill insulating layers 57A. In some embodiments, each of the oxygen adsorption layers 59 is located between a corresponding (e.g., abutting) one of the second liner layers 56A and a corresponding (e.g., abutting) one of the second gap-fill insulating layers 57A. Upper surfaces of the second gap-fill insulating layers 57A and upper surfaces of the oxygen adsorption layers 59 may be located on substantially the same plane. The oxygen adsorption layers 59 may surround lower surfaces of the second gap-fill insulating layers 57A. The second liner layers 56A may surround the lower surfaces of the second gap-fill insulating layers 57A. In the cross-sectional view of FIG. 5B, the second liner layers 56A and the oxygen adsorption layers 59 may each have a U shape.

The second deck D2 may include second row lines RL2, second column lines CL2, second memory cells MC2, first liner layers 54B, first gap-fill insulating layers 55B, second liner layers 56B, and second gap-fill insulating layers 57B.

The second row lines RL2 may extend in the first direction I, and the second column lines CL2 may extend in the second direction II. The second column lines CL2 may be electrically connected to the first column lines CL1. The second memory cells MC2 may be located at intersection regions between the second row lines RL2 and the second column lines CL2. Each second memory cell MC2 may include a first electrode 51B, a second electrode 52B, and a variable resistance layer 53B.

The first liner layers 54B may be formed on sidewalls of the second row lines RL2 and sidewalls of the second memory cells MC2. The first gap-fill insulating layers 55B may be located between the second memory cells MC2 adjacent to each other in the second direction II.

The second liner layers 56B may be formed on sidewalls of the second column lines CL2 and sidewalls of the second memory cells MC2. The second gap-fill insulating layers 57B may be located between the second memory cells MC2 adjacent to each other in the first direction I.

For reference, it is also possible for the semiconductor device to include the oxygen adsorption layers 19, 29, 39, and 49 according to embodiments described with reference to FIGS. 1A to 1C, 2A, 2B, 3A, 3B, 4A, and 4B or include a combination of the oxygen adsorption layers 19, 29, 39, and 49. As an example, the semiconductor device may include the oxygen adsorption layer 39 or the oxygen adsorption layer 49 instead of the oxygen adsorption layer 59, and the oxygen adsorption layer 39 or the oxygen adsorption layer 49 may be spaced apart from the second column line CL2. For example, when the oxygen adsorption layer 39 or 49 replaces the oxygen adsorption layer 59 according to an embodiment, the oxygen adsorption layer 39 or 49 may be spaced apart from a lower surface of the second column line CL2 in the third direction III.

According to the structure described above, the semiconductor device having a multi-deck structure may include the oxygen adsorption layer 59. Through this, the second liner layers 56A and the variable resistance layers 53A may be protected, and the reliability of the semiconductor device may be improved.

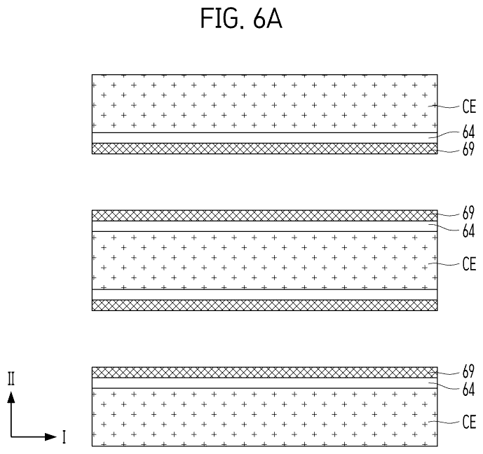

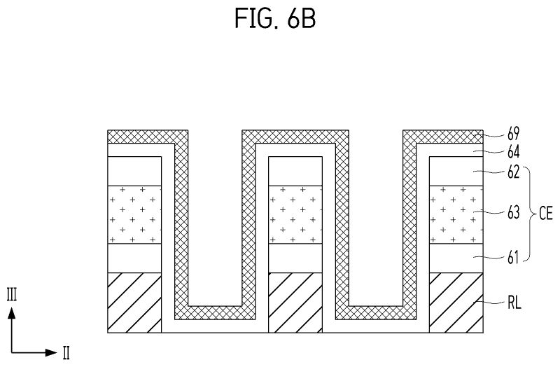

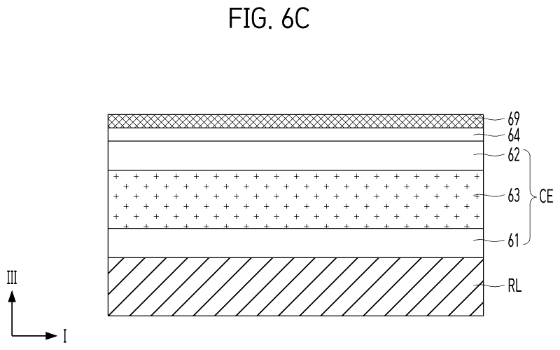

FIGS. 6A, 7A, and 8A, FIGS. 6B, 7B, and 8B, and FIGS. 6C, 7C, and 8C are diagrams for describing a manufacturing method of a semiconductor device in accordance with an embodiment. FIGS. 6A, 7A, and 8A are plan views, FIGS. 6B, 7B, and 8B are cross-sectional views in the second direction II, and FIGS. 6C, 7C, and 8C are cross-sectional views in the first direction I. Hereinafter, the content overlapping with the previously described content may be omitted for the interest of brevity.

Referring to FIGS. 6A to 6C, a first initial electrode layer is formed on a conductive layer, an initial variable resistance layer is formed on the first initial electrode layer, and a second initial electrode layer is formed on the initial variable resistance layer. Subsequently, cell lines CE, each of which extends in the first direction I and includes the second electrode layer 62, the variable resistance layer 63, and the first electrode layer 61 may be formed by etching the initial second electrode layer, the initial variable resistance layer, and the initial first electrode layer. Subsequently, row lines RL extending in the first direction I may be formed by etching the conductive layer.

Subsequently, a first liner layer (or an initial first liner layer) 64 may be formed on the cell lines CE. The first liner layer 64 may be conformally formed along a profile of the cell lines CE. The first liner layer 64 is used to protect the variable resistance layer 63 in a manufacturing process, and may include nitride.

Subsequently, an oxygen adsorption layer 69 may be formed on the first liner layer 64. The oxygen adsorption layer 69 may be conformally formed along a profile of the first liner layer 64. The oxygen adsorption layer 69 may include metal. As an example, the oxygen adsorption layer 69 may include at least one of zirconium (Zr), titanium (Ti), hafnium (Hf), tantalum (Ta), tungsten (W), cobalt (Co), nickel (Ni), silicon (Si), germanium (Ge), lanthanum (La), or aluminum (Al).

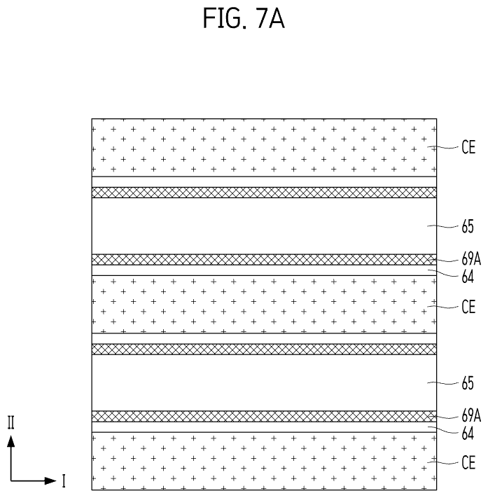

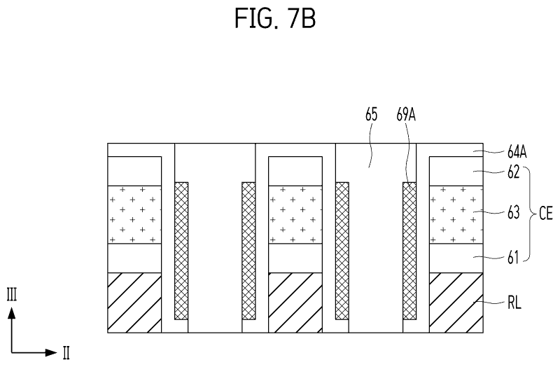

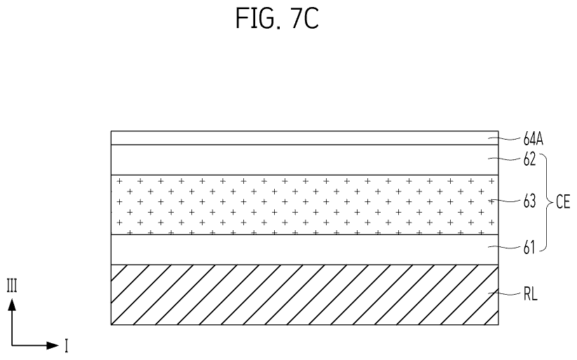

Referring to FIGS. 7A to 7C, the oxygen adsorption layer 69 is etched. As an example, the oxygen adsorption layer (or an initial oxygen adsorption layer) 69 may be etched using an etch-back process. For example, portions of the oxygen adsorption layer 69 formed on upper surfaces of the cell lines CE may be etched. In some embodiments, portions of the oxygen adsorption layer 69 formed between the cell lines CE adjacent to each other in the second direction II may be etched. For example, portions of the oxygen adsorption layer 69 adjacent to the upper surfaces of the cell lines CE may be etched. Through this, the etched oxygen adsorption layers (or intermediate oxygen adsorption layers) 69A each having a spacer shape may be formed. The etched oxygen adsorption layers 69A may be located on sidewalls of the cell lines CE, and may extend in the first direction I. For example, each of the etched oxygen adsorption layers 69A may be located on a sidewall of a corresponding (e.g., adjacent to) one of the cell lines CE, and extend in the first direction I. Upper surfaces of the etched oxygen adsorption layers 69A may be located lower than the upper surfaces of the cell lines CE.

In an etching process, portions of the first liner layer 64 formed between the cell lines CE may also be etched. The etched first liner layers 64A (or intermediate first liner layers) may surround the cell lines CE, respectively.

Subsequently, first gap-fill insulating layers 65 may be formed. For example, each of the first gap-fill insulating layers 65 may be formed between a pair of the cell lines CE adjacent to each other in the second direction II. A gap-fill insulating material may be formed to fill spaces between the cell lines CE, and be then planarized. A planarization process may be performed by a chemical mechanical polish (CMP) method. Through this, the first gap-fill insulating layers 65 extending in the first direction I may be formed.

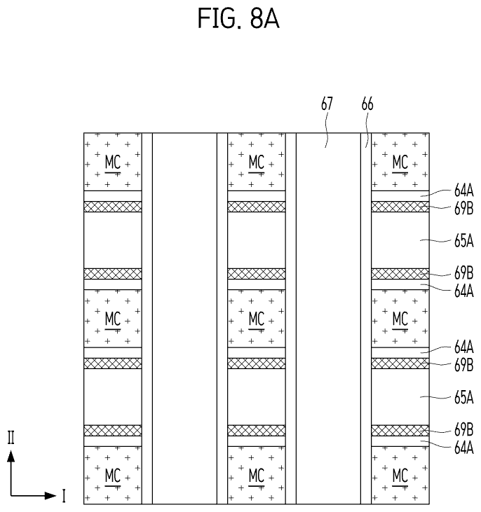

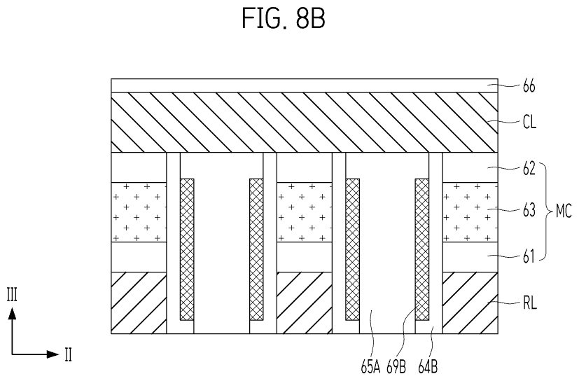

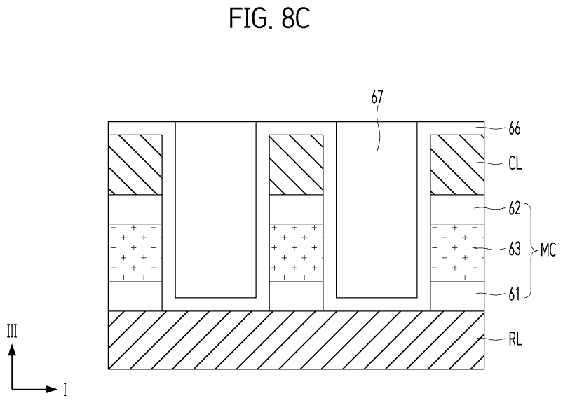

Referring to FIGS. 8A to 8C, column lines CL extending in the second direction II are formed by forming a conductive layer on the cell lines CE and etching the conductive layer. Subsequently, memory cells MC arranged in the first direction I and the second direction II may be formed by etching the cell lines CE. Oxygen adsorption layers 69B located on sidewalls of the memory cells MC adjacent to each other in the second direction II may be formed by etching the oxygen adsorption layers (or intermediate oxygen adsorption layers) 69A. First liner layers 64B located on the sidewalls of the memory cells MC adjacent to each other in the second direction II may be formed by etching the first liner layers (or intermediate first liner layers) 64A. Etched first gap-fill insulating layers 65A located between the memory cells MC adjacent to each other in the second direction II may be formed by etching the first gap-fill insulating layers 65.

Subsequently, a second liner layer 66 is formed along surfaces of the column lines CL, the memory cells MC, and the row lines RL. Subsequently, second gap-fill insulating layers 67 may be formed by forming a gap-fill insulating material on the second liner layer 66 and planarizing the gap-fill insulating material. The second gap-fill insulating layers 67 may be located between the column lines CL adjacent to each other in the first direction I and between the memory cells MC adjacent to each other in the first direction I. For example, each of the second gap-fill insulating layers 67 may be located between a pair of the column lines CL adjacent to each other in the first direction I. The second gap-fill insulating layers 67 may extend in the second direction II.

According to the manufacturing method described above, the oxygen adsorption layers 69B may be formed between the first liner layers 64B and the first gap-fill insulating layers 65A. When the oxygen adsorption layers 69B are not formed, the first liner layers 64B and the first gap-fill insulating layers 65A may come into direct contact with each other, and oxygen remaining inside the first gap-fill insulating layers 65A may react with the first liner layers 64B to damage the first liner layers 64B. Accordingly, by forming the oxygen adsorption layers 69B, it is possible to reduce the reaction of the remaining oxygen with the first liner layers 64B and reduce damage to the first liner layer 64B.

The oxygen adsorption layers 69B each having a spacer shape may be formed on the sidewalls of the memory cells MC. The oxygen adsorption layers 69B may be located lower than the memory cells MC, and may be located to be spaced apart from the column lines CL. Accordingly, even though the oxygen adsorption layers 69B each include the metal, it is possible to substantially prevent a bridge from occurring between the column lines CL due to the oxygen adsorption layers 69B.

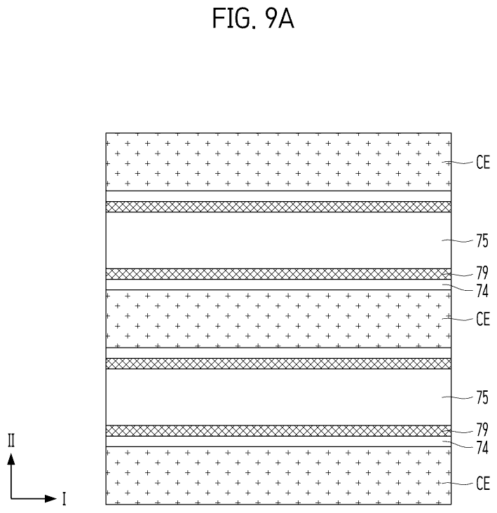

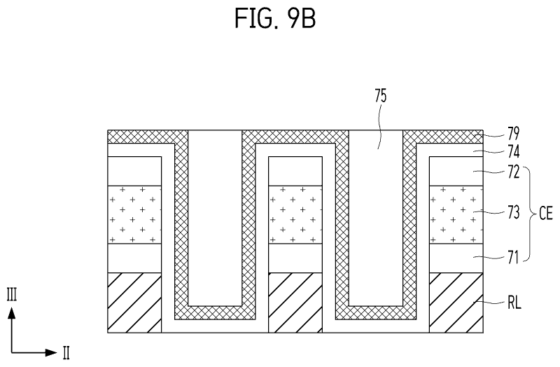

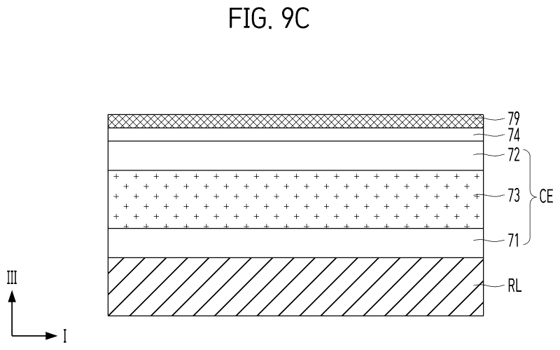

FIGS. 9A, 10A, and 11A, FIGS. 9B, 10B, and 11B, and FIGS. 9C, 10C, and 11C are diagrams for describing a manufacturing method of a semiconductor device in accordance with an embodiment. FIGS. 9A, 10A, and 11A are plan views, FIGS. 9B, 10B, and 11B are cross-sectional views in the second direction II, and FIGS. 9C, 10C, and 11C are cross-sectional views in the first direction I. Hereinafter, the content overlapping with the previously described content may be omitted for the interest of brevity.

Referring to FIGS. 9A to 9C, an initial first electrode layer, an initial variable resistance layer, and an initial second electrode layer are formed on a conductive layer. Subsequently, cell lines CE, each of which extends in the first direction I and includes the second electrode layer 72, the variable resistance layer 73, and the first electrode layer 71, may be formed by etching the initial second electrode layer, the initial variable resistance layer, and the initial first electrode layer. Subsequently, row lines RL extending in the first direction I may be formed by etching the conductive layer.

Subsequently, a first liner layer 74 is formed on the cell lines CE. Subsequently, an oxygen adsorption layer (or an initial oxygen adsorption layer) 79 may be formed on the first liner layer 74. The oxygen adsorption layer 79 may include metal. As an example, the oxygen adsorption layer 79 may include at least one of zirconium (Zr), titanium (Ti), hafnium (Hf), tantalum (Ta), tungsten (W), cobalt (Co), nickel (Ni), silicon (Si), germanium (Ge), lanthanum (La), or aluminum (Al).

Subsequently, first gap-fill insulating layers (or initial first gap-filling insulating layers) 75 are formed on the oxygen adsorption layer 79. As an example, the first gap-fill insulating layers 75 may be formed by forming a gap-fill insulating material on the oxygen adsorption layer 79 and then planarizing the gap-fill insulating material. The first gap-fill insulating layers 75 may be located between the cell lines CE adjacent to each other in the second direction II, and may extend in the first direction I.

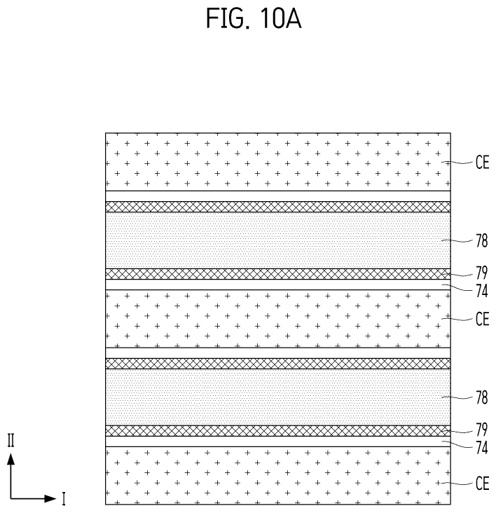

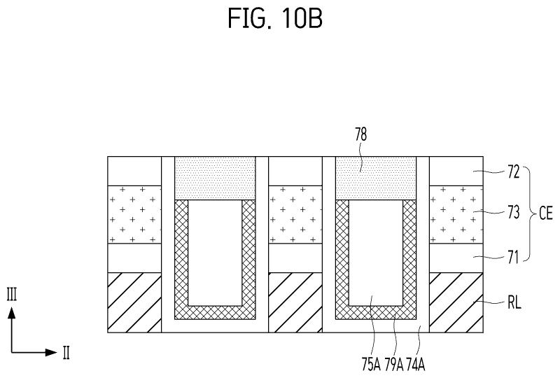

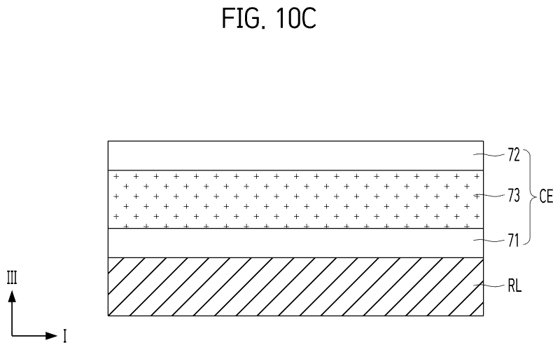

Referring to FIGS. 10A to 10C, the oxygen adsorption layer 79 and the first gap-fill insulating layers 75 are etched. As an example, oxygen adsorption layers 79A and first gap-fill insulating layers 75A may be formed by selectively etching the oxygen adsorption layer 79 and the first gap-fill insulating layers 75. Upper surfaces of the etched oxygen adsorption layers (or intermediate oxygen adsorption layers) 79A and the etched first gap-fill insulating layers (or intermediate first gap-fill insulating layers) 75A may be located lower than upper surfaces of the cell lines CE. As an example, the upper surfaces of the etched oxygen adsorption layers 79A and the etched first gap-fill insulating layers 75A may be located lower than upper surfaces of the variable resistance layers 73.

Subsequently, second gap-fill insulating layers 78 may be formed. A gap-fill insulating material may be formed to fill spaces between the cell lines CE, and be then planarized until the upper surfaces of the cell lines CE are exposed. A planarization process may be performed by a chemical mechanical polish (CMP) method. Through this, the second gap-fill insulating layers 78 extending in the first direction I may be formed. The second gap-fill insulating layers 78 may be located on the etched oxygen adsorption layers 79A and the etched first gap-fill insulating layers 75A, and may extend in the first direction I.

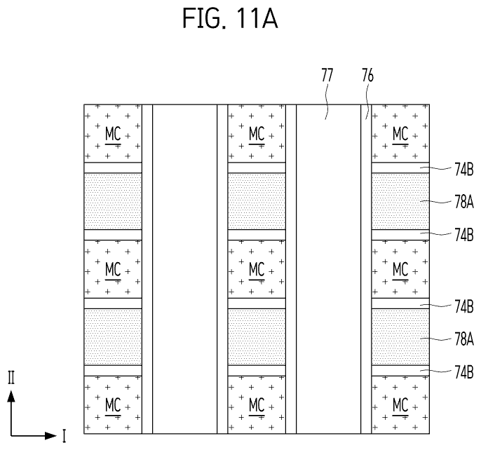

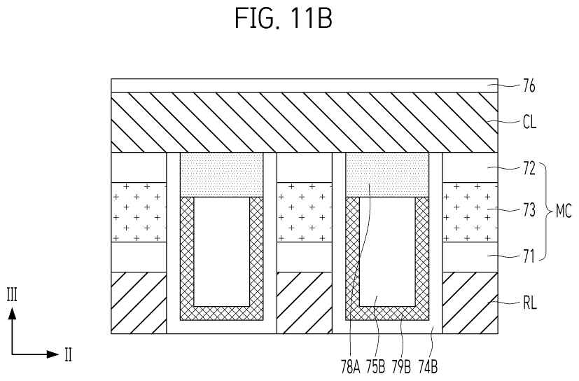

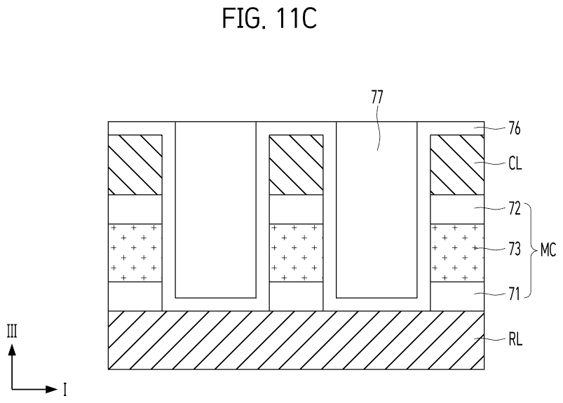

Referring to FIGS. 11A to 11C, column lines CL extending in the second direction II are formed by forming a conductive layer on the cell lines CE and etching the conductive layer. Subsequently, memory cells MC arranged in the first direction I and the second direction II may be formed by etching the cell lines CE. Oxygen adsorption layers 79B located on sidewalls of the memory cells MC adjacent to each other in the second direction II may be formed by etching the oxygen adsorption layers (or intermediate oxygen adsorption layers) 79A. First liner layers 74B located on the sidewalls of the memory cells MC adjacent to each other in the second direction II may be formed by etching first liner layers (or intermediate first liner layers) 74A. Second gap-fill insulating layers 78A located between the memory cells MC adjacent to each other in the second direction II may be formed by etching the second gap-fill insulating layers (or initial second gap-fill insulating layers) 78.

Subsequently, a second liner layer 76 is formed along surfaces of the column lines CL, the memory cells MC, and the row lines RL. Subsequently, third gap-fill insulating layers 77 may be formed by forming a gap-fill insulating material on the second liner layer 76 and planarizing the gap-fill insulating material. The third gap-fill insulating layers 77 may be located between the column lines CL adjacent to each other in the first direction I and between the memory cells MC adjacent to each other in the first direction I. The third gap-fill insulating layers 77 may extend in the second direction II.

According to the manufacturing method described above, by forming the oxygen adsorption layers 79B between the first liner layers 74B and the first gap-fill insulating layers 75B, it is possible to substantially prevent damage to the first liner layer 74B. By forming the second gap-fill insulating layers 78A between the oxygen adsorption layers 79B and the column lines CL, it is possible to substantially prevent a bridge from occurring between the column lines CL. In addition, the first liner layer 74B may be reinforced with the second gap-fill insulating layers 78A.

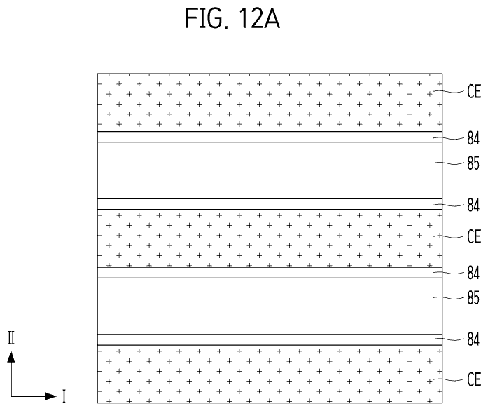

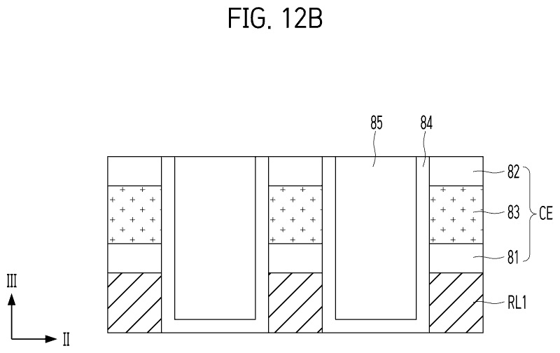

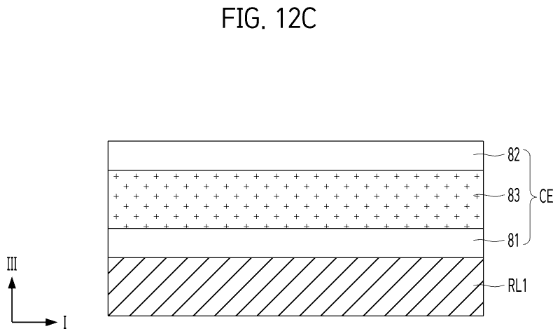

FIGS. 12A, 13A, and 14A, FIGS. 12B, 13B, and 14B, and FIGS. 12C, 13C, and 14C are diagrams for describing a manufacturing method of a semiconductor device in accordance with an embodiment. FIGS. 12A, 13A, and 14A are plan views, FIGS. 12B, 13B, and 14B are cross-sectional views in the second direction II, and FIGS. 12C, 13C, and 14C are cross-sectional views in the first direction I. Hereinafter, the content overlapping with the previously described content may be omitted for the interest of brevity.

Referring to FIGS. 12A to 12C, first row lines RL1, cell lines CE, first liner layers 84, and first gap-fill insulating layers 85 may be formed. The first row lines RL1, the cell lines CE, and the first gap-fill insulating layers 85 may extend in the first direction I. Each cell line CE may include a first electrode layer 81, a second electrode layer 82, and a variable resistance layer 83.

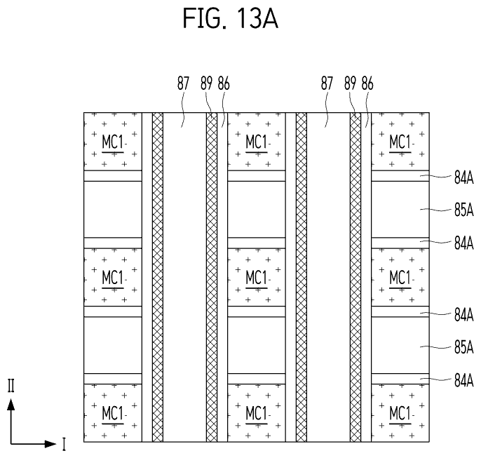

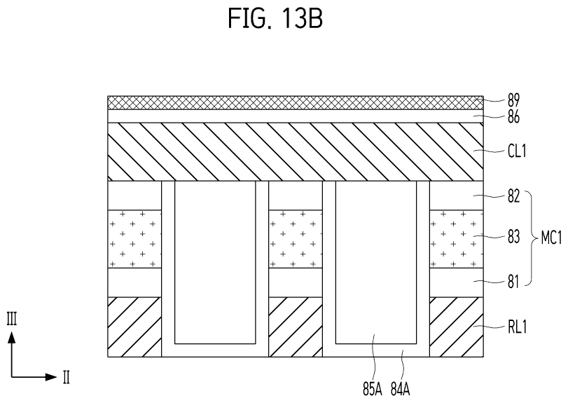

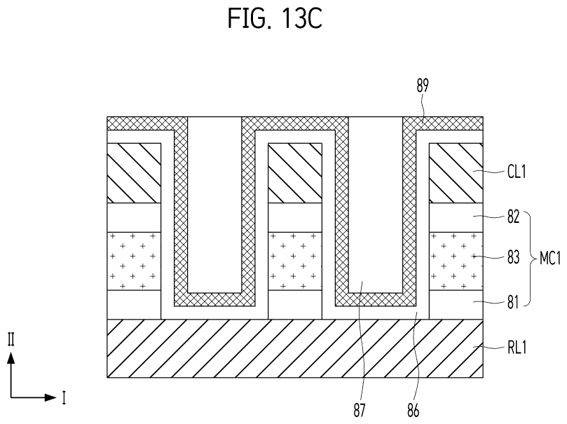

Referring to FIGS. 13A to 13C, first column lines CL1 extending in the second direction II are formed by forming a conductive layer above the cell lines CE and etching the conductive layer. Subsequently, first memory cells MC1 arranged in the first direction I and the second direction II may be formed by etching the cell lines CE. First liner layers 84A located on the sidewalls of the first memory cells MC1 adjacent to each other in the second direction II may be formed by etching the first liner layers 84 of FIGS. 12A to 12C. First gap-fill insulating layers 85A located between the first memory cells MC1 adjacent to each other in the second direction II may be formed by etching the first gap-fill insulating layers 85.

Subsequently, a second liner layer 86 is formed along surfaces of the first column lines CL1, the first memory cells MC1, and the first row lines RL1. Subsequently, an oxygen adsorption layer 89 may be formed on the second liner layer 86. The oxygen adsorption layer 89 may be conformally formed along a profile of the second liner layer 86. The oxygen adsorption layer 89 may include metal. As an example, the oxygen adsorption layer 89 may include at least one of zirconium (Zr), titanium (Ti), hafnium (Hf), tantalum (Ta), tungsten (W), cobalt (Co), nickel (Ni), silicon (Si), germanium (Ge), lanthanum (La), or aluminum (Al).

Subsequently, second gap-fill insulating layers 87 may be formed by forming a gap-fill insulating material on the oxygen adsorption layer 89 and planarizing the gap-fill insulating material. The second gap-fill insulating layers 87 may be located between the first column lines CL1 adjacent to each other in the first direction I and between the first memory cells MC1 adjacent to each other in the first direction I. The second gap-fill insulating layers 87 may extend in the second direction II.

For reference, similar to the embodiment described above with reference to FIGS. 6A, 7A, and 8A, FIGS. 6B, 7B, and 8B, and FIGS. 6C, 7C, and 8C, the oxygen adsorption layer 89 may be etched. Alternatively, similar to the embodiment described above with reference to FIGS. 9A, 10A, and 11A, FIGS. 9B, 10B, and 11B, and FIGS. 9C, 10C, and 11C, the oxygen adsorption layer 89 may be etched, and a gap-fill insulating layer may be additionally formed.

Consequently, a first deck D1 including the first row lines RL1, the first memory cells MC1, and the first column lines CL1 may be formed. Subsequently, a second deck D2 including second row lines RL2, second memory cells MC2, and second column lines CL2 may be formed on the first deck D1.

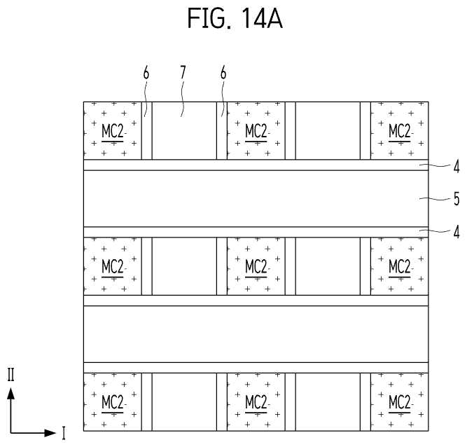

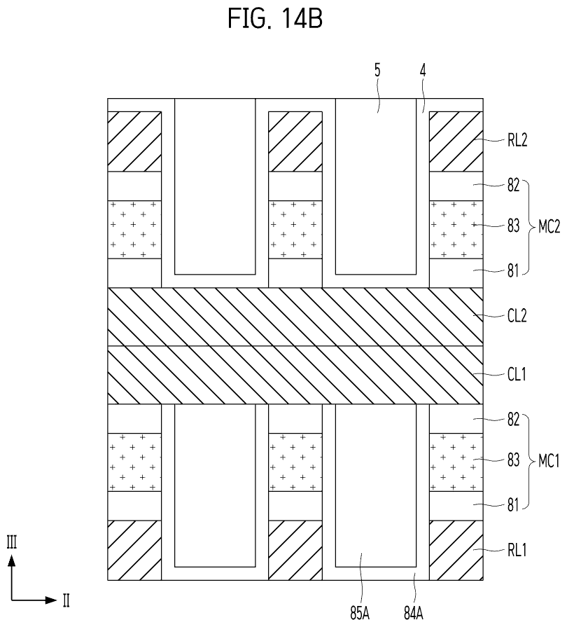

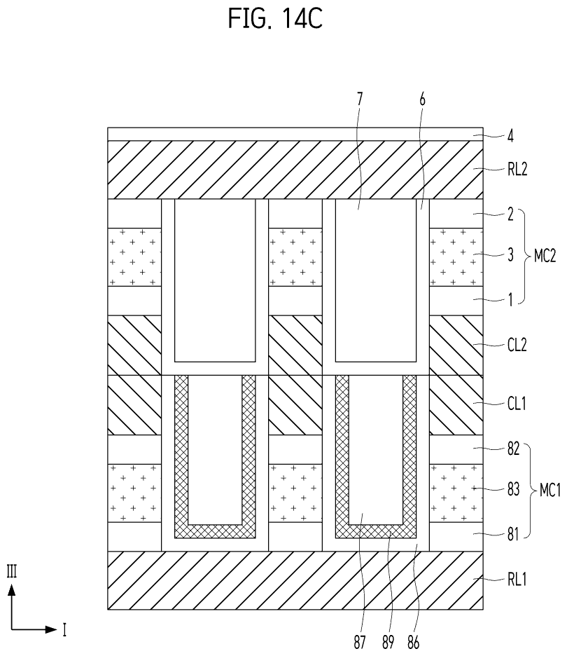

Referring to FIGS. 14A to 14C, cell lines and second column lines CL2 extending in the second direction II may be formed, and first liner layers 6 and first gap-fill insulating layers 7 may be formed. Subsequently, second row lines RL2 extending in the first direction I may be formed. Subsequently, second memory cells MC2 arranged in the first direction I and the second direction II may be formed by etching the cell lines. Subsequently, second liner layers 4 and second gap-fill insulating layers 5 may be formed. For reference, similar to the embodiment described above with reference to FIGS. 6A, 7A, 8A, 9A, 10A, 11A, 12A, and 13A, FIGS. 6B, 7B, 8B, 9B, 10B, 11B, 12B, and 13B, and FIGS. 6C, 7C, 8C, 9C, 10C, 11C, 12C, and 13C, it is also possible to form an oxygen adsorption layer in the second deck D2.

According to the manufacturing method described above, the oxygen adsorption layers 89 may be formed between the second liner layers 86 and the second gap-fill insulating layers 87. Accordingly, damage to the second liner layer 86 may be reduced, and the variable resistance layers 83 may be protected. In addition, by forming the first deck D1 and/or the second deck D2 to include the oxygen adsorption layers, the reliability of the semiconductor device may be improved.

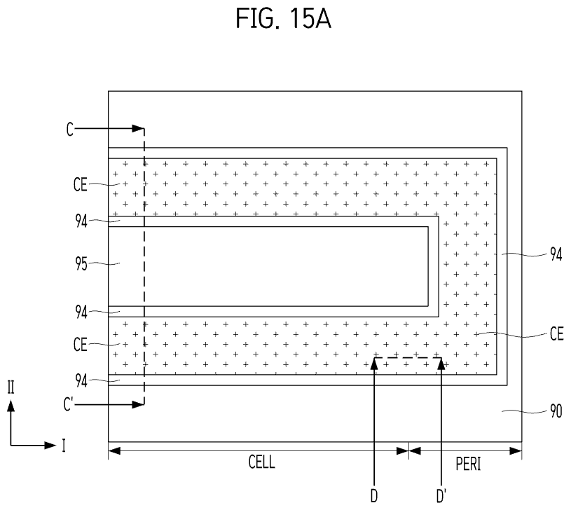

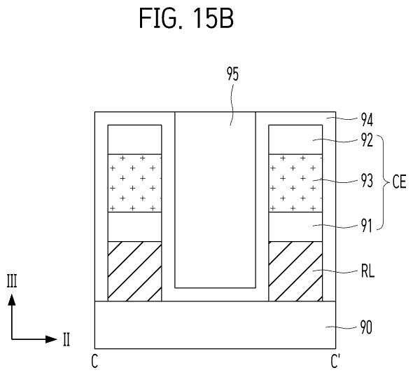

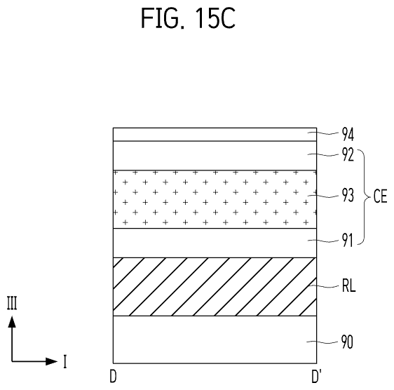

FIGS. 15A, 16A, and 17A, FIGS. 15B, 16B, and 17B, and FIGS. 15C, 16C, and 17C are diagrams for describing a manufacturing method of a semiconductor device in accordance with an embodiment. FIGS. 15A, 16A, and 17A are plan views, FIGS. 15B, 16B, and 17B are cross-sectional views taken along lines C-C′ of FIGS. 15A, 16A, and 17A, respectively, and FIGS. 15C, 16C, and 17C are cross-sectional views taken along lines D-D′ of FIGS. 15A, 16A, and 17A, respectively. Hereinafter, the content overlapping with the previously described content may be omitted for the interest of brevity.

Referring to FIGS. 15A to 15C, an insulating layer 90 may be formed on a substrate (not illustrated) including a cell region CR and a peripheral region PERI. As an example, a peripheral circuit may be formed in the peripheral region PERI of the substrate, an interconnection structure electrically connected to the peripheral circuit may be formed, and an interlayer insulating layer may be formed on the substrate. Here, the cell region CR is a region where memory cells are formed, and the peripheral region PERI is a region where one or more peripheral circuits for driving the memory cells, the interconnection structure, and the like, are formed. The peripheral circuits may include a row decoder, a column decoder, and the like, and the interconnection structure may include a via, a wiring line, and the like.

Subsequently, a stack pattern including a variable resistance layer 93 is formed on the insulating layer 90. The stack pattern may extend in the first direction I, and may have a U shape at an end portion thereof. As an example, the stack pattern may include row lines RL and cell lines CE. The row lines RL and the cell lines CE may extend in the first direction I, and may each have a U shape in which end portions thereof are connected to each other when seen in the plan view of FIG. 15A. Each cell line CE may include a first electrode layer 91, a second electrode layer 92, and the variable resistance layer 93.

Subsequently, a first liner layer 94 and first gap-fill insulating layers 95 may be formed on the stack pattern. As an example, the first liner layer 94 may be formed on the row lines RL and the cell lines CE, and the first gap-fill insulating layers 95 may be formed on the first liner layer 94. The first gap-fill insulating layers 95 may be located between the cell lines CE adjacent to each other in the second direction II, and may extend in the first direction I. For reference, although not illustrated in FIGS. 15A to 15C, it is also possible to form an oxygen adsorption layer on the first liner layers 94.

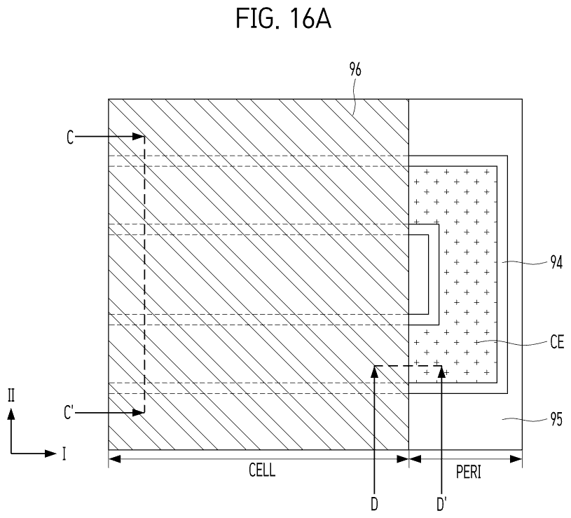

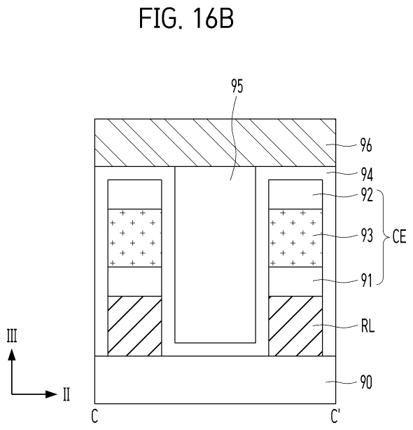

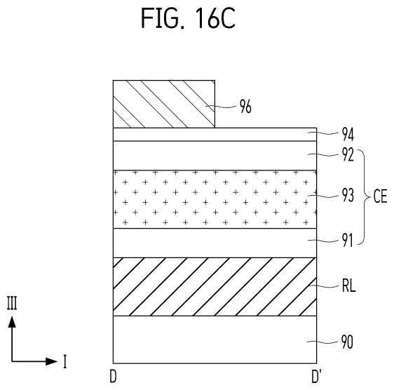

Referring to FIGS. 16A to 16C, a mask pattern 96 is formed on the first gap-fill insulating layers 95. The mask pattern 96 may have a shape in which it covers the cell region CR and exposes the peripheral region PERI. The mask pattern 96 may expose the end portions of the cell lines CE.

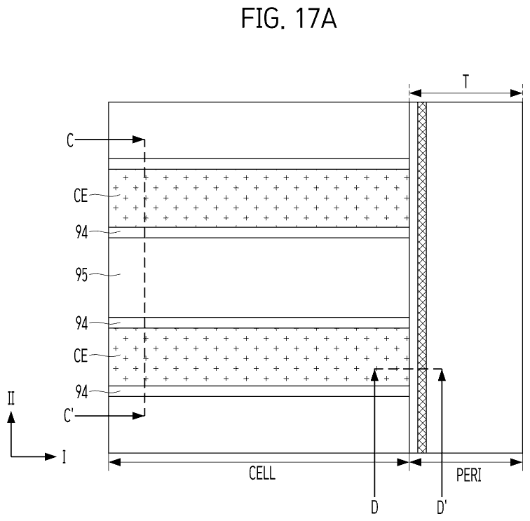

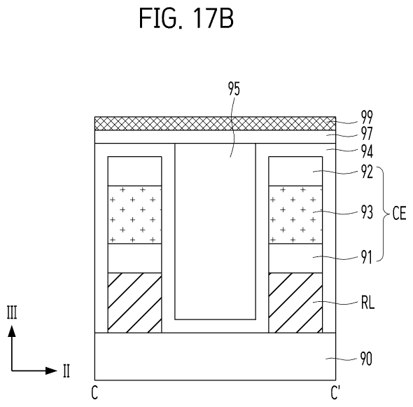

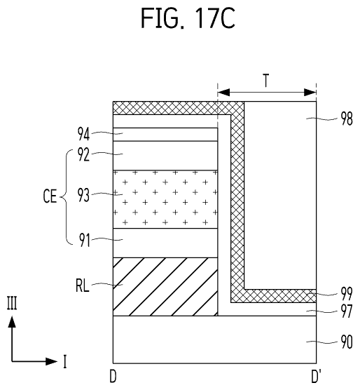

Referring to FIGS. 17A to 17C, a trench T may be formed by etching the end portions of the stack pattern so that the stack pattern is separated into stack line patterns. As an example, the first gap-fill insulating layers 95, the first liner layer 94, the cell lines CE and the row lines RL may be etched using the mask pattern 96 as an etching barrier. Through this, the end portions of the cell lines CE and the row lines RL may be etched, and the cell lines CE and the row lines RL each have a line shape.

Subsequently, a second liner layer 97 may be formed on sidewalls of the stack line patterns exposed through the trench. As an example, the second liner layer 97 may be formed on the first liner layers 94, the first gap-fill insulating layers 95, the cell lines CE, and the insulating layer 90. The second liner layer 97 is used to protect the variable resistance layers 93, and may include nitride. Subsequently, an oxygen adsorption layer 99 may be formed on the second liner layer 97. The oxygen adsorption layer 99 may be conformally formed along a profile of the second liner layer 97. The oxygen adsorption layer 99 may include metal. As an example, the oxygen adsorption layer 99 may include at least one of zirconium (Zr), titanium (Ti), hafnium (Hf), tantalum (Ta), tungsten (W), cobalt (Co), nickel (Ni), silicon (Si), germanium (Ge), lanthanum (La), or aluminum (Al).

Subsequently, a second gap-fill insulating layer 98 may be formed in the trench T. As an example, the second gap-fill insulating layer 98 may be formed by forming a gap-fill insulating material on the oxygen adsorption layer 99 and planarizing the gap-fill insulating material. The second gap-fill insulating layer 98 may be located in the peripheral region PERI, and may include oxide.

Subsequently, although not illustrated in FIGS. 17A to 17C, column lines, memory cells, and the like, may be formed. The column lines may be separated to each have a line shape by etching end portions of the column lines that together form a U-shape using a mask pattern. In addition, an oxygen adsorption layer may be formed on the liner layers by combining the embodiments described above. For example, a trench may be formed by etching end portions of the column lines, a liner layer may be formed on sidewalls of the etched column lines exposed through the trench, forming an oxygen adsorption layer on the liner layer, and forming a gap-fill insulating layer in the trench.

According to the manufacturing method described above, the oxygen adsorption layer 99 may be formed between the second liner layers 97 and the second gap-fill insulating layer 98. Accordingly, it is possible to substantially prevent the second liner layers 97 from being damaged due to oxygen remaining in the second gap-fill insulating layer 98, and it is possible to protect the variable resistance layers 93.

Although some embodiments of the present disclosure have been described above with reference to the accompanying drawings, various embodiments of the present disclosure are not limited to the above-described embodiments. Various types of substitutions, modifications, changes, and combinations for the embodiments may be made by those skilled in the art, to which the present disclosure pertains, and these substitutions, modifications, changes, and combinations belong to the scope of embodiments of the present disclosure.

What is claimed is:

1. A semiconductor device comprising:
row lines extending in a first direction;
column lines extending in a second direction that intersects the first direction;
memory cells located at intersection regions between the row lines and the column lines;
first liner layers formed on sidewalls of the row lines and sidewalls of the memory cells;
first gap-fill insulating layers located between the memory cells adjacent to each other in the second direction; and
first oxygen adsorption layers located between the first liner layers and the first gap-fill insulating layers and spaced apart from the column lines.

2. The semiconductor device of claim 1, wherein each of the first liner layers is formed on the sidewall of a corresponding one of the row lines and the sidewall of a corresponding one of the memory cell,
wherein each of the first gap-fill insulating layers is located between a pair of the memory cells adjacent to each other in the second direction, and
wherein each of the first oxygen adsorption layers is located between a corresponding one of the first liner layers and a corresponding one of the first gap-fill insulating layers and spaced apart from a corresponding one of the column lines.

3. The semiconductor device of claim 1, wherein upper surfaces of the first oxygen adsorption layers are located lower than upper surfaces of the memory cells.

4. The semiconductor device of claim 1, wherein the first oxygen adsorption layers each include metal.

5. The semiconductor device of claim 1, wherein the first oxygen adsorption layers each include metal oxide.

6. The semiconductor device of claim 1, further comprising second gap-fill insulating layers located on the first oxygen adsorption layers and the first gap-fill insulating layers.

7. The semiconductor device of claim 6, wherein the first gap-fill insulating layers each include oxide, and the second gap-fill insulating layers each include nitride.

8. The semiconductor device of claim 6, wherein the first oxygen adsorption layers surround lower surfaces of the first gap-fill insulating layers.

9. The semiconductor device of claim 1, further comprising:
second liner layers formed on sidewalls of the column lines and sidewalls of the memory cells; and
second gap-fill insulating layers located between the memory cells adjacent to each other in the first direction.

10. The semiconductor device of claim 9, further comprising second oxygen adsorption layers located between the second liner layers and the second gap-fill insulating layers.

11. A semiconductor device comprising:
first row lines extending in a first direction;
first column lines extending in a second direction that intersects the first direction;
first memory cells located between the first row lines and the first column lines;
first liner layers formed on sidewalls of the first memory cells and sidewalls of the first column lines;
first gap-fill insulating layers located between the first memory cells adjacent to each other in the first direction; and
first oxygen adsorption layers located between the first liner layers and the first gap-fill insulating layers.

12. The semiconductor device of claim 11, wherein each of the first liner layers is formed on the sidewalls of a pair of the first memory cells adjacent to each other in the first direction and the sidewalls of a pair of the first column lines adjacent to each other in the first direction,
wherein each of the first gap-fill insulating layers is located between a pair of the first memory cells adjacent to each other in the first direction, and
wherein each of the first oxygen adsorption layers is located between a corresponding one of the first liner layers and a corresponding one of the first gap-fill insulating layers.

13. The semiconductor device of claim 11, wherein upper surfaces of the first oxygen adsorption layers are located lower than upper surfaces of the first column lines.

14. The semiconductor device of claim 11, further comprising second gap-fill insulating layers located on the first oxygen adsorption layers and the first gap-fill insulating layers.

15. The semiconductor device of claim 14, wherein the first gap-fill insulating layers each include oxide, and the second gap-fill insulating layers each include nitride.

16. The semiconductor device of claim 14, wherein the first oxygen adsorption layers surround lower surfaces of the first gap-fill insulating layers.

17. The semiconductor device of claim 11, further comprising:
second column lines electrically connected to the first column lines and extending in the second direction;
second row lines extending in the first direction; and
second memory cells located between the second column lines and the second row lines.

18. The semiconductor device of claim 17, wherein the first oxygen adsorption layers are spaced apart from the second column lines.

19. The semiconductor device of claim 11, wherein the first oxygen adsorption layers each include metal.

20. The semiconductor device of claim 11, wherein the first oxygen adsorption layers each include metal oxide.
